(19) United States
(12) Patent Application Publication
(10) Pub. No.: US 2009/0014833 A1
(43) Pub. Date: Jan. 15, 2009

(54) SEMICONDUCTOR DEVICE AND METHOD OF FABRICATING THE SAME

(75) Inventors: Kuk-Han YOON, Gyeonggi-do (KR); Jong-Kyu KIM, Gyeonggi-do (KR); Sang-Sup JEONG, Gyeonggi-do (KR); Sung-Gil CHOI, Gyeonggi-do (KR); Tae-Hyuk AHN, Gyeonggi-do (KR)

Correspondence Address: MARGER JOHNSON & MCCOLLOM, P.C., 210 SW MORRISON STREET, SUITE 400, PORTLAND, OR, 97204, US

(73) Assignee: SAMSUNG ELECTRONICS CO., LTD., Gyeonggi-do (KR)

(21) Appl. No.: 12/171,066

(22) Filed: Jul. 10, 2008

(30) Foreign Application Priority Data
Jul. 10, 2007 (KR) 10-2007-0069351

(51) Int. Cl. H01L 27/08

(52) U.S. Cl. 257/532; 257/E27.048

(57) ABSTRACT

An exemplary semiconductor device includes a semiconductor substrate on which lower electrodes are formed. The lower electrodes are arranged in an array including a rows extending substantially parallel to one another along a first direction. A stripe-shaped capacitor support pad is interposed between a pair of adjacent ones of the rows and is connected to lower electrodes in the pair of adjacent ones of the rows. The semiconductor device may include plurality of capacitors each including a one of the lower electrodes, a dielectric film, and an upper electrode. An upper end of the capacitor support pad is below the upper ends of the lower electrodes. A portion of the stripe-shaped capacitor support pad is interposed between adjacent ones of lower electrodes included within at least one of the rows and is connected to the adjacent ones of lower electrodes included within the at least one of the rows.

### CROSS-REFERENCE TO RELATED PATENT APPLICATIONS

This application claims the benefit of foreign priority to Korean Patent Application No. 10-2007-0069351, filed on Jul. 10, 2007, the disclosure of which is incorporated herein in its entirety by reference.

### BACKGROUND

1. Field of Invention

Embodiments of the present invention relate generally to semiconductor devices and methods of fabricating the same. More particularly, embodiments of the present invention relate to a semiconductor device including capacitors and a method of fabricating the same.

2. Description of the Related Art

As areas occupied by semiconductor devices continue to become reduced with an increasing degree of integration of those semiconductor devices with DRAM cells, the cell capacitance of the DRAM cells must be maintained or increased. Generally, sufficient cell capacitance within a limited area can sometimes be maintained by using a high dielectric material as a dielectric film in the DRAM cell, reducing the thickness of the dielectric film in the DRAM cell, increasing the effective area of a lower electrode in the DRAM cell, etc. Among these, use of high dielectric material requires a large investment in terms of materials and time (e.g., introduction of new facilities, assurance of reliability and mass-production of dielectric films, subsequent low temperature processes, etc). Accordingly, methods of increasing the effective area of a lower electrode in the DRAM cell are usually employed since conventional dielectric films can be used and processes thereof can be realized easily.

Some methods of increasing the effective area of lower electrodes, are understood to include making lower electrodes in a three-dimensional shape (e.g., a cylinder shape, a fin shape, etc.), growing hemispherical grain (HSG) structures on lower electrodes, increasing the height of the lower electrodes, etc. Among these methods, the method of growing HSG structures on the lower electrodes may prevent the securing of a critical dimension between the lower electrodes. In addition, sometimes the HSG structures may become detached from the lower electrodes, resulting in the formation of conductive bridges between lower electrodes. Also, it is difficult to grow HSG structures in semiconductor devices having a design rule of less than 0.14 μm. Accordingly, methods of making lower electrodes with three-dimensional shapes and increasing the height of lower electrodes are commonly employed (e.g., by making the lower electrodes in a cylinder shape or of a stack-type) to increase the cell capacitance of a DRAM cell.

Dielectric material can be deposited on external surfaces, or external and internal surfaces, of the cylindrical and stack-type lower electrodes. Therefore, cylindrical and stack-type lower electrodes can have large effective areas. However, the height of a cylindrical or stack-type lower electrode having an integrated one cylinder stack (OCS) structure are usually increased to ensure a capacitance that is greater than a predetermined capacitance required to operate a semiconductor device. Therefore, a problem arises because cylindrical or stack-type lower electrode having an integrated OCS structure frequently fall down or break off before the deposition of a dielectric material.

One cause for the aforementioned problem can be attributed to the surface tension of a cleaning liquid used during a cleaning-liquid drying process after wet etching of a mold oxide film. Accordingly, methods of increasing the area of a lower electrode by conventional methods can be limited due to the aforementioned fall-down problem of the lower electrodes. Consequently, supporting pads have been developed in an attempt to solve the aforementioned fall-down problem.

Conventional supporting pads are generally formed in the shape of a lattice. When the lattice-shaped supporting pads are formed, all the lower electrodes can become undesirably twisted because the supporting pads themselves apply stress to the lower electrodes. In addition, the lattice-shaped supporting pads cause gaps between the lower electrodes to be narrow. As a result, materials cannot be deposited symmetrically and uniformly over the lower electrodes in subsequent processes. Consequently, the subsequent deposited materials may increase the stress on the lower electrodes, thereby further increasing the twisting of the lower electrodes.

In addition, lattice-shaped supporting pads are generally formed at the upper end portions of the lower electrodes. During the process of forming the lattice-shaped supporting pads at the upper end portions of the lower electrodes, the lower electrodes can be damaged, thereby reducing the capacitance of the subsequently-formed capacitor and generating a leakage current at the damaged portion, thereby creating a serious defect.

Further, a supporting pad pattern formed at the upper end portions of the lower electrodes is formed using a photoresist (PR) pattern. Use of the PR pattern can be problematic since the PR material flows into deep holes defined by the lower electrodes. In addition, the PR material cannot be removed completely. Also, since the supporting pad pattern formed at the upper end portions of the lower electrodes is formed through a supporting pad etching process while the lower electrodes are partially exposed, a nonvolatile polymer is formed during the supporting pad etching process. The formation of the nonvolatile polymer can be problematic since because it is not easily removed. As a result, a defect of the pattern or contamination of an etching reaction bath may occur.

### SUMMARY

Exemplary embodiments of the present invention can be generally characterized as capable of providing a semiconductor device including capacitors and having a capacitor support pad structure capable of preventing damage to lower electrodes, of preventing photoresist material from flowing into holes for lower electrodes, of preventing polymer formation, and the like, while ensuring sufficient space between lower electrodes, and to a method of fabricating the same.

One embodiment exemplarily described herein can be generally characterized as a semiconductor device that includes a semiconductor substrate in which a cell region is defined. A plurality of lower electrodes may be formed above the cell region. The plurality of lower electrodes may be arranged in an array including a plurality of rows extending substantially parallel to one another along a first direction. A stripe-shaped capacitor support pad may be interposed between a pair of adjacent ones of the plurality of rows and may be connected to lower electrodes in the pair of adjacent ones of the plurality of rows. The semiconductor device may include a plurality of capacitors each including, for example, a corresponding one of the plurality of lower electrodes, a dielectric film, and an upper electrode. An upper end of the capacitor support pad may be below the upper ends of the plurality of lower electrodes and a portion of the stripe-shaped capacitor support pad may be interposed between adjacent ones of lower electrodes included within at least one of the plurality of rows and be connected to the adjacent ones of lower electrodes included within the art least one of the plurality of rows.

### BRIEF DESCRIPTION OF THE DRAWINGS

The above and other embodiments of the present invention will become more apparent with reference to the attached drawings in which:

FIG. 1A is a plan view illustrating a semiconductor device according to an embodiment of the present invention;

FIG. 1B is a cross-sectional view taken along the line 1b-1b in FIG. 1A; and

FIG. 2 and FIGS. 3A through 7B are plan and cross-sectional views illustrating an exemplary method of fabricating the semiconductor device shown in FIGS. 1A and 1B, according to an embodiment of the present invention.

### DETAILED DESCRIPTION

Exemplary embodiments of the present invention will now be described in detail with reference to the attached drawings. In the following descriptions, when a component element is described to be positioned above another component element, this means that the component element may be positioned just on another component element, or a third component element may be interposed between them. In addition, thickness and size of each component element shown in the drawings are exaggerated for the convenience and clearness of descriptions, and portions not related to descriptions are omitted. In the drawings, similar reference numerals denote similar members. Meanwhile, terms used in the descriptions are used only for the purpose of describing the present invention, are not intended to be construed in limiting meanings and the scope of the present invention defined by the claims.

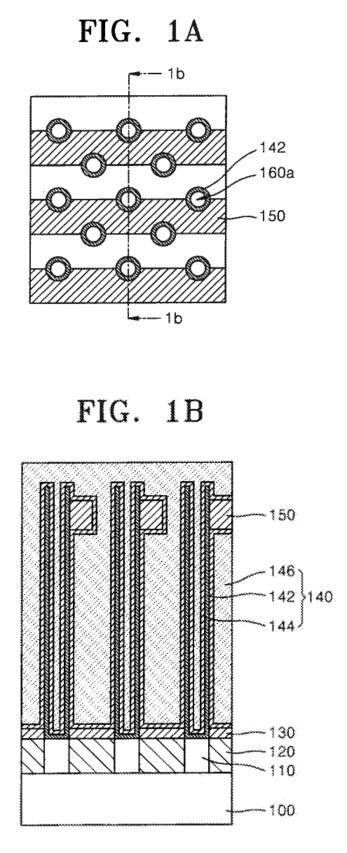

FIG. 1A is a plan view of a semiconductor device according to an embodiment of the present invention, and shows the semiconductor device before a dielectric material is applied to lower electrodes.

Referring to FIG. 1A, in the semiconductor device, capacitor support pads 150 for supporting the lower electrodes 142 of capacitors are formed in the shape of stripes over a cell region of a semiconductor substrate. That is, the capacitor support pads 150 are stripe-shaped. The lower electrodes 142 may, for example, be arranged in an array that includes a plurality of rows. Each of the rows may extend substantially along a first direction and each of the rows may include a plurality of lower electrodes 142. Accordingly, within each of the rows, a plurality of lower electrodes 142 may be substantially aligned with each other along the first direction. That is, within each of the rows, centerlines of the plurality of lower electrodes 142 may be substantially collinear along the first direction. Although FIG. 1A illustrates the plurality of rows extending horizontally when viewed in plan view, it will be appreciated that the plurality of rows may extend in any direction when viewed in plan view (e.g., vertical, diagonal, etc.). In one embodiment, each of the stripe-shaped capacitor support pads 150 may be formed between a pair of neighboring rows. Accordingly, each of the stripe-shaped capacitor support pads 150 may connect lower electrodes 142 included in different rows to each other. Likewise, the lower electrodes 142 in each pair of neighboring rows may be connected to each other by a corresponding capacitor support pad 150.

In one embodiment, between a pair of neighboring rows, lower electrodes 142 are not substantially aligned with each other along a second direction that is substantially perpendicular to the first direction. That is, between pairs of neighboring rows, centerlines of the plurality of lower electrodes 142 are not substantially collinear along the second direction. Since the lower electrodes 142 are not substantially aligned with each other along the second direction, relatively wide spaces can be formed between adjacent lower electrodes 146 of neighboring rows (i.e., the pitch between neighboring lower electrodes 142 can be made relatively large). As a result, material (e.g., a dielectric material) can be deposited relatively uniformly in subsequent processes.

In addition, since the capacitor support pads 150 are formed to have the shape of stripes, an exposure process used to form a pattern of the capacitor supporting pads 150 can be performed more easily. For example, a photoresist (PR) pattern for a stripe-shaped pattern is much simpler than a PR pattern for a conventional lattice-shaped pattern and the size of the former is greater than that of the latter. Therefore, the PR pattern of the stripe-shaped pattern is formed very easily during an exposure process.

Although FIG. 1A illustrates the stripe-shaped capacitor support pads 150 as extending substantially along the first direction (i.e., the direction along which the plurality of rows extend, or a “row direction”), it will be appreciated that the present invention is not limited thereto. For example, the capacitor support pads 150 may be formed to substantially extend along the aforementioned second direction (i.e., a “column direction”) or any direction between the first and second directions (i.e., a “diagonal direction”). Also, although not shown, the stripe-shaped capacitor support pads 150 may be formed to extend to or beyond the boundary of the cell region (i.e., cell block edges). In addition, two or more capacitor support pads 150 may be formed to connect to each other at edge portions of the cell region in order to increase the support given to the lower electrodes 142.

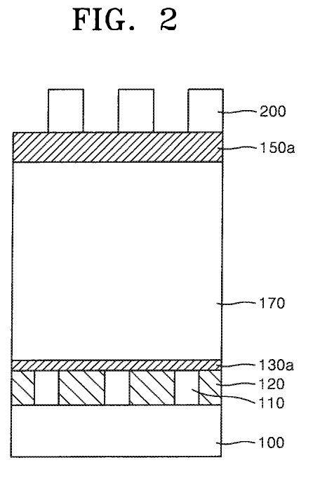

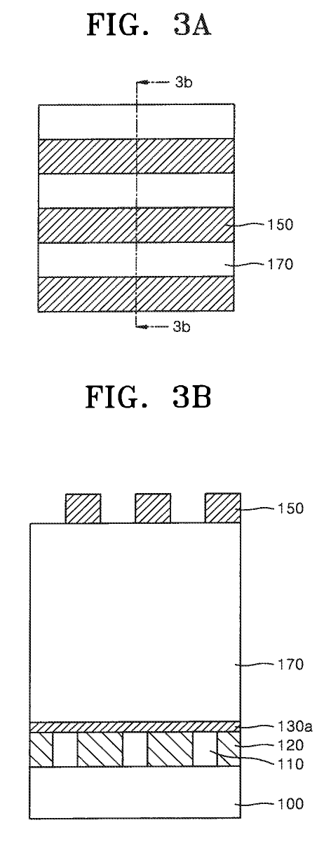

In the illustrated embodiment, the capacitor support pads 150 are formed not at upper end portions of the lower electrodes 142, but slightly below the upper end portions of the lower electrodes 142. That is, upper end portions of the capacitor support pads 150 are below upper end portions of the lower electrodes 142. A detailed description of such a construction will be provided with reference to FIG. 1B, FIG. 2, and FIGS. 3A through 7B.

FIG. 1B is a cross-sectional view taken along line 1b-1b shown in FIG. 1A, and shows the semiconductor device after a dielectric film and upper electrode are formed.

Referring to FIG. 1B, the semiconductor device may include a semiconductor substrate 100, cylindrical capacitors 140 formed above the semiconductor substrate 100, and capacitor support pads 150 for supporting the lower electrodes 142 of the cylindrical capacitors 140.

As mentioned above, the semiconductor substrate 100 includes a cell region (shown) and also includes a peripheral circuit region (not shown) surrounding the cell region. Contact lines 110, connected to conductive regions of the cell region, and an inter-layer insulating film 120 are formed on the semiconductor substrate 100. In one embodiment, the contact lines 110 are sections of a layer serving to electrically connect the conductive regions of the cell region with corresponding ones of the lower electrodes 142. In another embodiment, the contact lines 110 may be, for example, storage node contact plugs.

Each capacitor 140 may, for example, include a cylindrical lower electrode 142, a dielectric film 144 and an upper electrode 146, and may be disposed on a corresponding one of the contact lines 110. In one embodiment, the cylindrical lower electrode 142 is formed to a height of about 10,000 Å to about 20,000 Å, and the ratio of height to diameter may tend to increase gradually with increasing height. Therefore, as described above, the capacitor support pads 150 are provided to prevent the lower electrodes 142 from falling down. Also shown in FIG. 1B is an etching stop film 130 formed of a material such as silicon nitride (SiN). The etching stop film 130 may be formed on the inter-layer insulating film 120.

In one embodiment, the capacitor support pad 150 has a thickness of about 100 Å to about 5,000 Å. In another embodiment, the capacitor support pad 150 may be formed at a position of about 500 Å to about 5,000 Å below the upper end of the lower electrode 142. It will be appreciated, however, that the thickness and position of the capacitor support pad 150 are not limited to the above values.

According to the illustrated embodiment, the lower electrodes 142 are substantially prevented from falling down or breaking down because the capacitor support pads 150 are formed in the shape of stripes between the lower electrodes 142. In addition, a photoresist process for forming the capacitor support pads 150 can be performed easily. Accordingly, all the lower electrodes 142 can be formed substantially symmetrically and substantially uniformly, and subsequent materials can be deposited substantially uniformly in subsequent processes.

According to the illustrated embodiment, the capacitor support pads 150 are formed slightly below the upper end portions of the lower electrodes 142, to solve a problem occurring when a support pad pattern is formed while conventional lower electrodes are in an exposed state. That is, because the capacitor support pads 150 are formed at slightly below the upper end portions of the lower electrodes 142, a problem in which conventional lower electrodes are unsymmetrical as a whole because the upper end portions of the conventional lower electrodes are damaged, a problem of polymer formation, a problem of removing photoresist and the like can be solved. Detailed descriptions thereof will be given in connection with descriptions of an exemplary method of fabricating the semiconductor device with reference to FIGS. 2 and 3A through 7B.

FIG. 2 and FIGS. 3A through 7B are plan and cross-sectional views illustrating an exemplary method of fabricating the semiconductor device shown in FIGS. 1A and 1B, according to an embodiment of the present invention. FIGS. 3B, 4B, 5B, 6B and 7B are cross-sectional views of 3A, 4A, 5A, 6A and 7A, respectively.

Referring to FIG. 2, the contact lines 110, the inter-layer insulating film 120, and an etching stop film 130a are formed on the semiconductor substrate 100, a first mold oxide film 170 is formed on the etching resist film 130a and a support pad film 150a is formed on the first mold oxide film 170. The first mold oxide film 170 facilitates the subsequent formation of capacitors. Photoresist patterns 200 are formed on the support pad film 150a. The photoresist patterns 200 facilitate the subsequent patterning of the support pad film 150a into capacitor support pads 150. In some embodiments, the photoresist patterns 200 may be formed in the shape of stripes in a row, column and/or diagonal directions, depending on the shape of capacitor support pads 150 intended to be formed.

Since the photoresist patterns 200 are formed to have the shape of stripes so as to form the capacitor support pads 150 having the shape of stripes, the photoresist patterns 200 can be formed much easier than a photoresist pattern for a conventional lattice-shaped support pad. That is, since it is easier to obtain the shape of the photoresist patterns 200 than it is with conventional photoresist patterns, and since the width of the space between the photoresist patterns 200 is wider than that between conventional photoresist patterns, an exposure process can be performed relatively easily. In addition, since the photoresist patterns 200 are formed before holes for the lower electrodes are formed, a conventional problem in which photoresist material flows into deep holes formed by lower electrodes, thus making it difficult to remove the photoresist material, can be prevented.

In one embodiment, the support pad film 150a is formed of a material having an etch rate different from that of the first mold oxide film 170. In another embodiment, a lift-off process may, for example, be used with a LAL solution to remove the first mold oxide film 170. Therefore, the support pad film 150a may be formed of a material having a relatively low etch rate in the LAL solution. In another embodiment, the support pad film 150a may include a material having dielectric characteristics. For example, if an embodiment where the first mold oxide film 170 includes SiO₂, SiGe, Si, a carbonaceous material film, or the like, the support pad film 150a can include a material such as SiN, SiCN, TaO, TiO₂, or the like. It will be appreciated, however, that the support pad film 150a can include materials other than SiN, SiCN, TaO, and TiO₂.

Referring to FIGS. 3A and 3B, the capacitor support pads 150 and the first mold oxide film 170, exposed between the capacitor support pads 150, are shown. Stripe-shaped patterns of the capacitor support pads 150 may be formed in a dry etching process using the photoresist patterns 200 as etching masks.

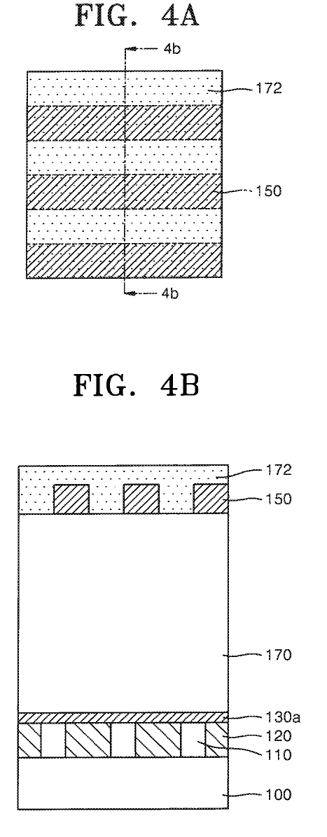

Referring to FIGS. 4A and 4B, a second mold oxide film 172 is formed on the exposed first mold oxide film 170 on which the capacitor support pads 150 are formed, so as to cover the capacitor support pads 150. In one embodiment, the second mold oxide film 172 is formed completely on the exposed first mold oxide film 170. It one embodiment, the second mold oxide film 172 is formed of the same material (or substantially the same material) as that of the first mold oxide film 170. In another embodiment, the second mold oxide film 172 is formed of a material having a similar etch rate to that of the first mold oxide film 170 such that, for example, the difference between etch rates of the second mold oxide film 172 and the first mold oxide film 170 is less than about 10% in a LAL solution (the first and second mold oxide films 170 and 172 may be removed by a lift-off process using a LAL solution). The second mold oxide films 172 have a thickness sufficient to substantially fill gaps between the capacitor support pads 150. For example, the second mold oxide film 172 can be formed to have a thickness of about 1,000 Å to about 10,000 Å.

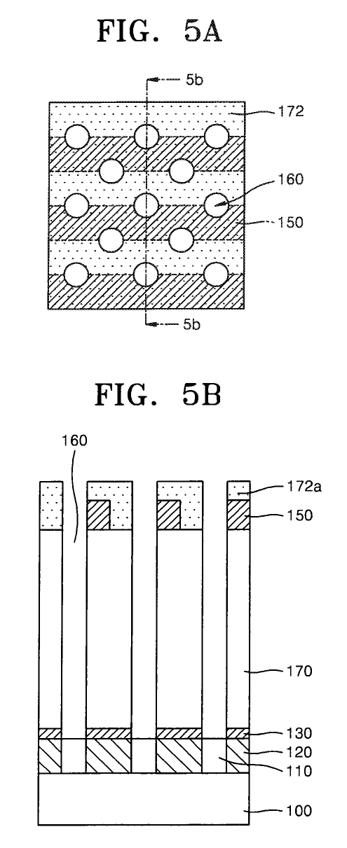

Referring to FIGS. 5A and 5B, a plurality of holes 160 are formed at positions where lower electrodes are to be subsequently formed. The plurality of holes 160 may, for example, be formed by dry etching the first and second mold oxide films 170 and 172, the capacitor support pads 150 and the etching stop film 130 until the contact lines 110 are exposed. Such holes 160 are formed in an array including a plurality of rows. Although FIG. 5A illustrates the plurality of rows extending horizontally when viewed in plan view, it will be appreciated that the plurality of rows may extend in any direction when viewed in plan view (e.g., vertical, diagonal, etc.). In one embodiment, each of the rows of holes 160 may extend substantially along a first direction and each of the rows may include a plurality of holes 160. Accordingly, within each of the rows, a plurality of holes 160 may be substantially aligned with each other along the first direction. Between a pair of neighboring rows, holes 160 are not substantially aligned with each other along a second direction that is substantially perpendicular to the first direction, thereby ensuring that relatively wide spaces are present between subsequently formed lower electrodes 142.

In the illustrated embodiment, each of the stripe-shaped capacitor support pads 150 may be formed between a pair of neighboring rows 160. Accordingly, each of the stripe-shaped capacitor support pads 150 may connect holes 160 included in different rows to each other. Likewise, the holes 160 in each pair of neighboring rows may be connected to each other by a corresponding capacitor support pad 150.

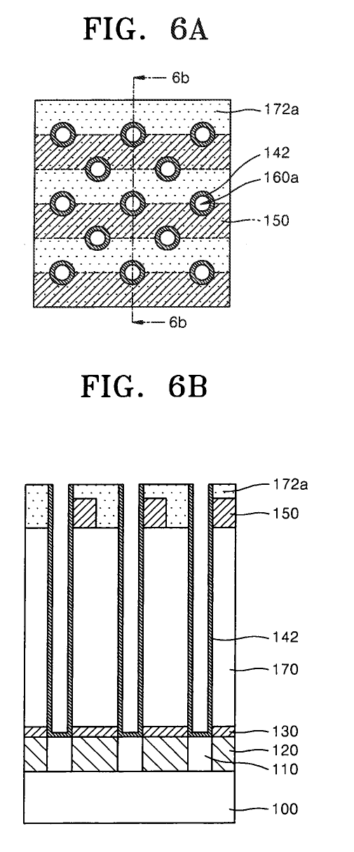

Referring to FIGS. 6A and 6B, after a conductive material is deposited on a whole surface of a resultant structure over the semiconductor substrate 100 (i.e., on inner surfaces of the holes 160 and on top surfaces of the second mold oxide film pattern 172a), a node separation process for forming the lower electrodes 142 is performed. In such a node separation process, a sacrificial oxide film (not shown) is formed on the whole surface of the resultant structure over the semiconductor substrate 100 so that holes 160a can be filled up after the conductive material is deposited. The sacrificial oxide film is then subjected to planarization and removal processes until the second mold oxide film 172a is exposed through an etch-back and/or chemical-mechanical planarization (CMP) process. In one embodiment, the conductive material for the lower electrodes 142 may, for example, include titanium nitride (TiN). In another embodiment, the portion of the sacrificial oxide film on the top surfaces of the conductive material is removed through an etch-back process and the portion of the conductive material on top surfaces of the second mold oxide film 172a is removed through a CMP process. Next, the portion of the sacrificial oxide film in the holes 160a is removed by etching. As a result, the lower electrodes 142 are formed.

Conventionally, support pads are formed at upper ends of lower electrodes. Therefore, because the lower electrodes are exposed through the aforementioned etch-back or CMP process and support pad films are thereafter patterned, there is a problem in that a non-volatile polymer such as TiFₓ is formed during an etching process during patterning the support pads. The non-volatile polymer is not easily removed. According to the principles of the embodiments exemplarily described herein, however, the aforementioned problem associated with non-volatile polymer formation can be avoided because the stripe-shaped capacitor support pads 150 are formed before the lower electrodes 142.

Conventionally, support pads are formed at upper ends of the lower electrodes. Therefore, because the exposed upper end portions of the lower electrodes are etched together during the forming of a support pad pattern, the lower electrodes become damaged, rendering the lower electrodes generally unsymmetrical. As a result, the capacitance of subsequently formed capacitors can be decreased and leakage currents can be generated. According to the principles of the embodiments exemplarily described herein, however, the aforementioned problem associated with unsymmetrical lower electrodes 142 can be avoided because the support pad film 150a is patterned before the lower electrodes 142 are formed.

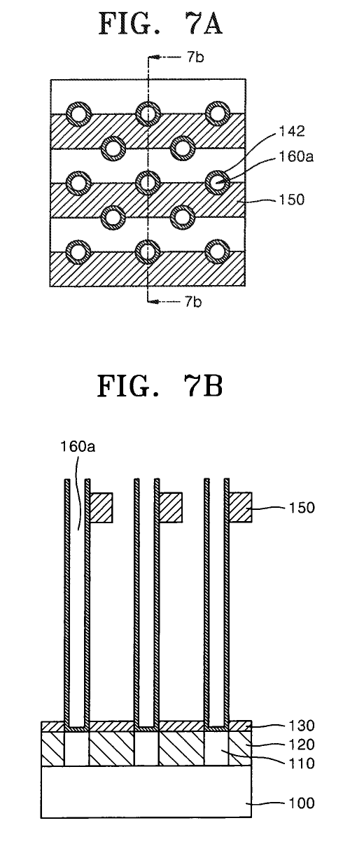

Referring to FIGS. 7A and 7B, after the node separation of the lower electrodes 142, the first mold oxide film 170 and the patterned second mold oxide film 172a may be removed by, for example, wet etching. In one embodiment, the first and second mold oxide films 170 and 172a can be removed through a lift-off process using HF and/or the LAL solution. In one embodiment, and as described above, the capacitor support pads 150 may be formed of a material having an etch rate lower than that of the first mold oxide film 170 and the patterned second mold oxide film 172a in the LAL solution.

In the embodiment illustrated in FIGS. 6A and 6B, the sacrificial oxide film is removed before the first mold oxide film 170 and patterned second mold oxide film 172a are removed. In another embodiment, however, material forming the sacrificial oxide film may be the same as (or substantially the same as), or similar to, the material(s) from which the first mold oxide film 170 and patterned second mold oxide film 172a are formed. In such an embodiment, the sacrificial oxide film can be removed together during the mold oxide film removing process shown in FIGS. 7A and 7B.

After the first mold oxide film 170 and the patterned second mold oxide film 172a are removed, the dielectric films 144 and the upper electrodes 146 are formed on the respective lower electrodes 142, thereby yielding the cylindrical capacitors 140 shown in FIGS. 1A and 1B.

Since the capacitor support pads 150 may be formed in the shape of stripes as described above, the first mold oxide film 170 and the patterned second mold oxide film 172a, and the like, are removed by wet etching such that spaces between the lower electrodes 142 are sufficiently wide, thereby allowing the dielectric films 144 and the upper electrodes 146 to be formed substantially symmetrically and substantially uniformly. In addition, since the capacitor support pads 150 are formed positions slightly below upper ends of the lower electrodes 142 before the holes 160 for the lower electrodes 142 are formed, the aforementioned problems of photoresist material flowing into the holes, non-volatile polymer formation, unsymmetrical capacitors, and the like, can be avoided.

According to the embodiments exemplarily described above, since capacitor support pads, for supporting lower electrodes of capacitors, are formed to have the shape of stripes and disposed between a portion of the lower electrodes in each pair of neighboring rows, columns, or diagonal rows, and since the supporting pads are formed not at upper ends of the lower electrodes but at positions that are at a predetermined distance below the upper ends of the lower electrodes, problems associated with lower electrode damage, removal of photoresist material within holes, polymer formation, and the like, can be prevented so that capacitors having high capacitance can be achieved.

As shown above, embodiments of the present invention may be practiced in many ways. What follows in the paragraphs below is a non-limiting description of some example embodiments.

One embodiment exemplarily described herein can be generally characterized as a method of fabricating a semiconductor device. The method may, for example, include preparing a semiconductor substrate in which a cell region; forming a first mold oxide film on the semiconductor substrate; forming a support pad film on the first mold oxide film; etching the support pad film to form a stripe-shaped capacitor support pad; forming a second mold oxide film on the first mold oxide film and the capacitor support pad; etching the first and second mold oxide films and the capacitor support pads over the cell region to form a plurality of holes which are arranged in an array including a plurality of rows, wherein each of the plurality of rows includes a plurality of holes; forming lower electrodes on inner surfaces of the holes; and forming a dielectric film and an upper electrode on the each of the plurality of lower electrodes and the capacitor support pad.

In one embodiment, the capacitor support pad may be interposed between a pair of adjacent ones of the plurality of rows, wherein lower electrodes in the first pair of adjacent ones of the plurality of rows are connected to each other by the capacitor support pad and wherein the capacitor support pad is stripe-shaped.

In one embodiment, lower electrodes within each of the plurality of rows may be substantially aligned with each other along a first direction extending across the semiconductor substrate and, between a pair of neighboring ones of the plurality of rows, lower electrodes may not be substantially aligned with each other along a second direction extending across the semiconductor substrate, wherein the second direction is substantially perpendicular to the first direction.

In one embodiment, the support pad film may be formed to extend to an edge portion of the cell region and forming a boundary portion of the cell region.

In one embodiment, the lower electrodes may be formed by a method that includes: forming a conductive material on an inner wall of the plurality of holes and a top surface of the second mold oxide film; forming a sacrificial oxide film on the conductive material; removing a portion of the sacrificial oxide film to expose a portion of the conductive material on the top surface of the second mold oxide film; and removing the exposed portion of the conductive material from the top surface of the second mold oxide film.

In one embodiment, the sacrificial oxide film and the first and second mold oxide films may be removed before forming the dielectric film.

In one embodiment, the support pad film may have an etch rate lower than that of the sacrificial oxide film and the first and second mold oxide films. The support pad film may include a dielectric material. The dielectric material may include at least one of SiN, SiCN, TaO, and TiO2.

In one embodiment, the support pad film may be formed to a thickness of about 100 Å to about 5,000 Å.

In one embodiment, the second mold oxide film may include an oxide material, wherein a difference between the etch rate of the oxide material and an etch rate of the first mold oxide film may be less than about 10%.

In one embodiment, the second mold oxide film may be formed to have a thickness greater than or substantially equal to a thickness of the capacitor support pad.

In one embodiment, the second mold oxide film may be formed to have a thickness of about 1,000 Å to about 10,000 Å.

While exemplary embodiments of the present invention have been particularly shown and described above, it will be understood by one skilled in the art that various changes in form and details may be made therein without departing from the spirit and scope of the invention as defined by the appended claims.

What is claimed is:

1. A semiconductor device comprising:
a semiconductor substrate in which a cell region is defined;
a plurality of lower electrodes formed above the cell region, wherein the plurality of lower electrodes are arranged in an array including a plurality of rows extending substantially parallel to one another along a first direction;
a stripe-shaped capacitor support pad interposed between a pair of adjacent ones of the plurality of rows and connected to lower electrodes in the pair of adjacent ones of the plurality of rows; and
a plurality of capacitors, wherein each of the plurality of capacitors includes a corresponding one of the plurality of lower electrodes, a dielectric film, and an upper electrode,
wherein an upper end of the capacitor support pad is below the upper ends of the lower electrodes, and
wherein a portion of the stripe-shaped capacitor support pad is interposed between adjacent ones of lower electrodes included within at least one of the plurality of rows and is connected to the adjacent ones of lower electrodes included within the at least one of the plurality of rows.

2. The semiconductor device of claim 1, wherein the plurality of lower electrodes are cylindrical lower electrodes.

3. The semiconductor device of claim 1, wherein upper ends of the plurality of lower electrodes are substantially coplanar.

4. The semiconductor device of claim 1, wherein distances between upper ends of adjacent ones of the plurality of lower electrodes along the same direction are substantially equal.

5. The semiconductor device of claim 1, wherein
lower electrodes within each of the plurality of rows are substantially aligned with each other along the first direction, and
between the pair of adjacent ones of the plurality of rows, lower electrodes are not substantially aligned with each other along a second direction extending across the semiconductor substrate, wherein the second direction is substantially perpendicular to the first direction.

6. The semiconductor device of claim 1, wherein the capacitor support pad extends to an edge portion of the cell region and forms a boundary portion of the cell region.

7. The semiconductor device of claim 6, further comprising two or more capacitor support pads, wherein the two or more capacitor support pads are connected to each other at the edge portion of the cell region.

8. The semiconductor device of claim 1, wherein the capacitor support pad has a thickness of about 100 Å to about 5,000 Å.

9. The semiconductor device of claim 8, wherein each of the plurality of lower electrodes have a height of about 10,000 Å to about 20,000 Å.

10. The semiconductor device of claim 9, wherein the upper end of the capacitor support pad is about 500 Å to about 5,000 Å below the upper end of at least one of the plurality of lower electrodes connected to another of the plurality of lower electrodes by the stripe-shaped capacitor support pad.

11. The semiconductor device of claim 1, wherein the capacitor support pad comprises a dielectric material.

12. The semiconductor device of claim 11, wherein the dielectric material comprises at least one of SiN, SiCN, TaO, and TiO₂.

13. The semiconductor device of claim 1, wherein the number of pairs of adjacent rows in the array is greater than the number of stripe-shaped capacitor support pads.

14. The semiconductor device of claim 1, wherein a width of the stripe-shaped capacitor support pad along a second direction extending across the semiconductor substrate substantially perpendicular to the first direction is less than a width of the array of the plurality of lower electrodes along the second direction.
